(19) United States
(12) Patent Application Publication
(10) Pub. No.: US 2015/0153420 A1
(43) Pub. Date: Jun. 4, 2015

(54) STATE-OF-CHARGE ESTIMATION METHOD AND STATE-OF-CHARGE ESTIMATION DEVICE

(71) Applicant: Kabushiki Kaisha Toyota Jidoshokki, Aichi (JP)

(72) Inventors: Hiroko Adaniya, Aichi (JP); Mitsugu Kobayashi, Aichi (JP); Takahiro Tsuzuki, Aichi (JP)

(73) Assignee: Kabushiki Kaisha Toyota Jidoshokki a corporation

(21) Appl. No.: 14/405,295

(22) PCT Filed: May 27, 2013
(86) PCT No.: PCT/JP2013/064625

§ 371 Date: Dec. 3, 2014

(30) Foreign Application Priority Data
Jun. 5, 2012 (JP) 2012-127634

(51) Int. Cl. G01R 31/36

(52) U.S. Cl. CPC G01R 31/3648; G01R 31/3606

(57) ABSTRACT

Voltage-change convergence time (τ) taken from the termination of charging and discharging of a secondary battery until the convergence of change in open-circuit voltage is measured in advance for each combination of the state-of-charge of the secondary battery at a charging and discharging termination time and the temperature of the secondary battery at the charging and discharging termination time. When the charging and discharging of the secondary battery is terminated in actual use, voltage-change convergence time (τ) corresponding to the temperature and the state-of-charge based on the integrated current value at the charging and discharging termination time is selected and the selected voltage-change convergence time (τ) is applied to a voltage characteristic formula.

### TECHNICAL FIELD

The present invention relates to a state-of-charge estimation method and state-of-charge estimation device for estimating the state of charge of a secondary battery.

### BACKGROUND ART

Examples of such state-of-charge estimation methods conventionally used include, for instance, the state-of-charge estimation method disclosed in Patent Literature 1 below. In conventional methods, the state of charge of a secondary battery is estimated through approximation, by a voltage characteristic expression, of the time change of an open-circuit voltage of the secondary battery, after termination of charge and discharge, and by calculating the open-circuit voltage from the voltage characteristic expression where the secondary battery is stable. Specifically, the open-circuit voltage of the secondary battery is measured a plurality of times over a predefined data acquisition period after termination of charge and discharge. The open-circuit voltage at stability is calculated by applying the measured open-circuit voltages to the voltage characteristic expression to work out parameters comprised in the voltage characteristic expression.

Patent Literature 1: Japanese Patent Application Publication No. 2008-96328

### DISCLOSURE OF THE INVENTION

The inventors studied the charge and discharge characteristics of various secondary batteries, and found out that a voltage-change convergence time τ from termination of charge and discharge of a secondary battery until convergence of a change in open-circuit voltage takes on a constant value for each combination of a state of charge of the secondary battery at the time of termination of charge and discharge, as estimated on the basis of an integrated current value or an estimated open-circuit voltage that is worked out using a closed-circuit voltage, and the temperature of the secondary battery at the time of termination of charge and discharge. In a conventional method, the measured open-circuit voltage is used only in a voltage characteristic expression, but a feature where the voltage-change convergence time τ takes on a constant value for each combination of temperature and slate of charge of a secondary battery at the time of termination of charge and discharge is not exploited. Accordingly a greater number of measured values of open-circuit voltage are necessary, and the time required for estimating the state of charge is longer. Herein, the estimated open-circuit voltage that is worked out using the closed-circuit voltage denotes an open-circuit voltage estimated on the basis of closed-circuit voltage and current.

With a view to solving the above problem, it is an object of the present invention to provide a state-of-charge estimation method and a state-of-charge estimation device that allow estimating the state of charge using smaller number of measured values of open-circuit voltage, and alto s shortening the time required for estimating the state of charge.

The state-of-charge estimation method according to the present invention is a state-of-charge estimation method for estimating a state of charge of a secondary battery by approximating a time change in an open-circuit voltage of the secondary battery after termination of charge and discharge by a voltage characteristic expression, and calculating the open-circuit voltage at stability of the secondary battery from the voltage characteristic expression, the method comprising the steps of: measuring beforehand a voltage-change convergence time τ from termination of charge and discharge of the secondary battery until convergence of change in the open-circuit voltage, for each combination of a state of charge of the secondary battery at the time of termination of charge and discharge and the temperature of the secondary battery at the time of termination of charge and discharge; and upon termination of the charge and discharge of the secondary battery, selecting the voltage-change convergence time τ corresponding to the state of charge and the temperature at the time of termination of charge and discharge, and using the selected voltage-change convergence time τ in the voltage characteristic expression.

The state-of-charge estimation device of the present invention is a: state-of-charge estimation device that calculates an open-circuit voltage at stability of a secondary battery from a voltage characteristic expression in which a time change of open-circuit voltage of the secondary battery is approximated after termination of charge and discharge, in order to estimate the state of charge of the secondary battery, the device comprising: a storage unit that stores a voltage-change convergence time τ from termination of charge and discharge of the secondary battery until convergence of change in the open-circuit voltage, for each combination of a state of charge of the secondary battery at the time of termination of charge and discharge and the temperature of the secondary battery at the time of termination of charge and discharge; and a computing unit that, upon termination of charge and discharge of the secondary battery, selects the voltage-change convergence time τ corresponding to the state of charge and the temperature at the time of termination of charge and discharge, and uses the selected voltage-change convergence time τ in the voltage characteristic expression.

The state-of-charge estimation method and state-of-charge estimation device of the present invention involve measuring beforehand a voltage-change convergence time τ from termination of charge and discharge of the secondary battery until convergence of change in the open-circuit voltage, for each combination of state of charge of the secondary battery at the time of termination of charge and discharge and the temperature of the secondary battery at the time of termination of charge and discharge, and upon termination of the charge and discharge of the secondary battery, selecting the voltage-change convergence time τ corresponding to the state of charge and the temperature at the time of termination of charge and discharge, and using the selected voltage-change convergence time τ in a voltage characteristic expression. Therefore, it becomes possible to estimate the state of charge using a smaller number of measured values of open-circuit voltage, and to shorten the time required for estimation of the state of charge.

### BRIEF DESCRIPTION OF THE DRAWINGS

FIG. 1 is an explanatory diagram illustrating the change in open-circuit voltage of a secondary battery after charging termination;

FIG. 2 is an explanatory diagram illustrating the change in open-circuit voltage of a secondary battery after discharge termination;

FIG. 3 is an explanatory diagram illustrating a map that includes a plurality of voltage-change convergence times τ measured beforehand based on a state-of-charge estimation method of the present embodiment;

FIG. 4 is a flowchart illustrating a state-of-charge estimation method after creation of the map of FIG. 3; and

FIG. 5 is a block diagram illustrating a state-of-charge estimation device for carrying out the state-of-charge estimation method of the present embodiment.

### BEST MODE FOR CARRYING OUT THE INVENTION

Modes for carrying out the present invention will be explained next with reference to accompanying drawings.

### Embodiment 1

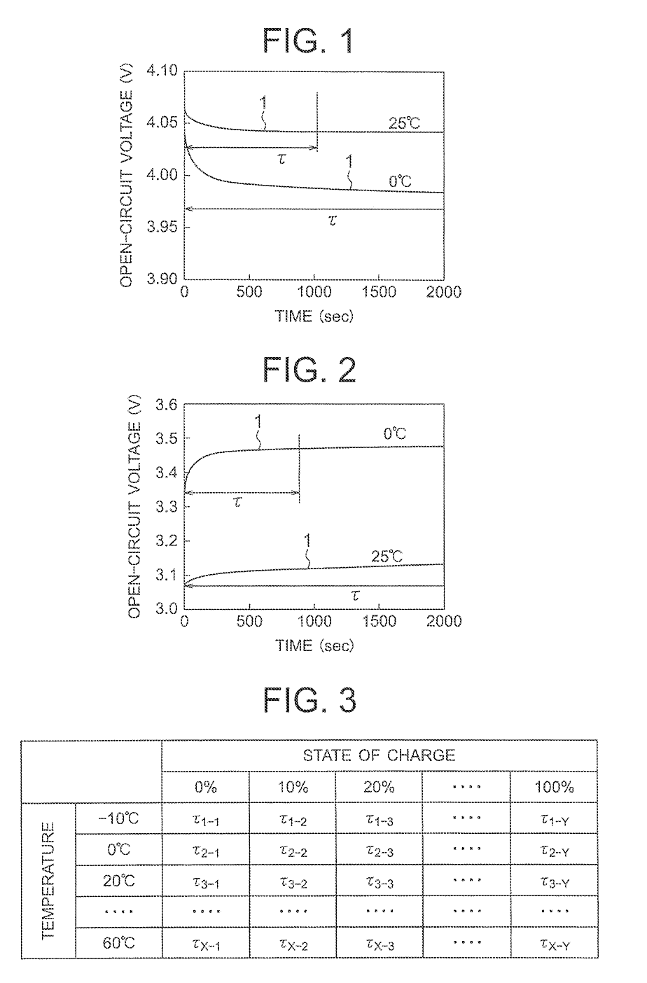

FIG. 1 is an explanatory diagram illustrating the change in open-circuit voltage of a secondary battery after charging termination, and FIG. 2 is an explanatory diagram illustrating the change in open-circuit voltage of a secondary battery after discharge termination. As illustrated in FIG. 1 and FIG. 2, an open-circuit voltage 1 of a secondary battery after termination of charge and discharge converges to a constant value after a predefined lapse of time from the time of termination of charge and discharge. The time elapsed since charge and discharge battery can be calculated from the voltage characteristic expression and the state of charge of the secondary battery can be estimated from the open-circuit voltage 1. The inventors found that the state of charge can be estimated, using a smaller number of measured values of open-circuit voltage, by using a voltage-change convergence time τ such as described above in a voltage characteristic expression. A state-of-charge estimation method wherein the voltage-change convergence time τ is used in a voltage characteristic expression will be explained next in further detail.

FIG. 3 is an explanatory diagram illustrating a map that includes a plurality of voltage-change convergence times τ measured beforehand on the basis of the state-of-charge estimation method of the present embodiment. As described above, the voltage-change convergence time τ depends on the state of charge of the secondary battery at the time of termination of charge and discharge, as estimated on the basis of the integrated current value or the like, and on the temperature of the secondary battery at the time of termination of charge and discharge. In the state-of-charge estimation method of the present embodiment, a map such as the one illustrated in FIG. 3 is created by measuring experimentally beforehand respective voltage-change convergence times τ_{1-1 . . . X-Y} for each combination of state of charge of the secondary battery at the time of termination of charge and discharge, as estimated on the basis of the integrated current value or the like, and temperature of the secondary battery at the time of termination of charge and discharge.

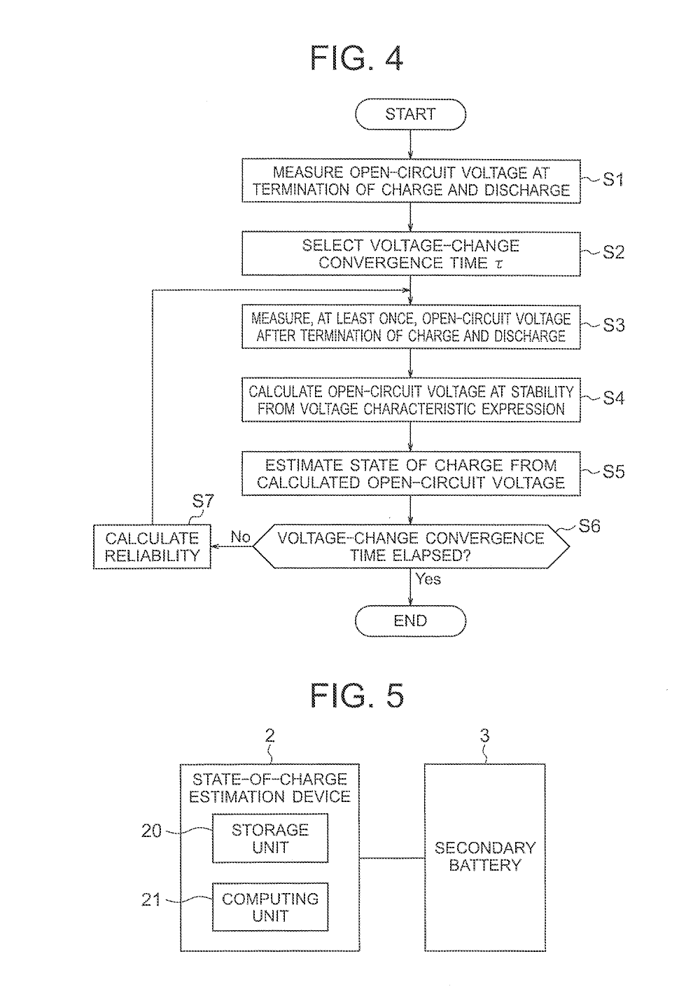

Next, FIG. 4 is a flowchart illustrating a state-of-charge estimation method after creation of the map of FIG. 3. Upon termination of charge and discharge of the secondary battery, the open-circuit voltage 1 at the time of termination of charge and discharge is measured (step S1), and a voltage-change convergence time τ corresponding to the state of charge and temperature of the secondary battery based on the integrated current value or the like at the time of termination of charge and discharge is selected from the map (step S2). Next, the open-circuit voltage 1 of the secondary battery after termination of charge and discharge is measured at least once at predefined measurement intervals, for instance of about several milliseconds to several seconds (step S3).

The open-circuit voltage 1 of the secondary battery after termination of charge and discharge is measured at least once, and thereafter, the open-circuit voltage 1 at stable secondary battery is calculated from the voltage characteristic expression (step S4), and the state of charge of the secondary battery is estimated from the calculated open-circuit voltage 1 (step S5).

The specific processes for calculating the open-circuit voltage 1 at stable secondary battery from the voltage characteristic expression will be explained next in further detail. Although various forms of voltage characteristic expression are conceivable, in the present embodiment the voltage characteristic expression is given by Expression (1) below.

V_{OCV}(t)=A₁ exp(−B₁t)+ . . . +Aₙ₊₁ exp(−Bₙ₊₁t)+V_{C} Expression (1)

In Expression (1), t is the time elapsed from the time of termination of charge and discharge, n is the number of measurements of the open-circuit voltage 1 after termination of charge and discharge, and A_{1 . . . n+1}, B_{1 . . . n+1}, V_{C} are parameters that make up the voltage characteristic expression. The terms relating to time on the right of Expression (1) (terms other than V_{C}) approximate the change in the open-circuit voltage 1 after termination of charge and discharge. The term V_{C} on the right of Expression (1) represents the open-circuit voltage 1 at stable secondary battery. The number of terms relating to time increases and decreases in accordance with the number of measurements of the open-circuit voltage after termination of charge and discharge. The more terms that relate to time, the higher the precision of the open-circuit voltage 1 as calculated on the basis of the voltage characteristic expression.

A differential expression of Expression (1) is given by Expression (2) below.

V′_{OCV}(t)=−B₁A₁ exp(−B₁t)− . . . −Bₙ₊₁Aₙ₊₁ exp(−Bₙ₊₁t) Expression (2)

Expression (3) below is obtained by substituting, in (1), the voltage-change convergence time τ selected in step S2.

V_{OCV}(τ)=A₁ exp(−B₁τ)+ . . . +Aₙ₊₁ exp(−Bₙ₊₁τ)+V_{C}=V_{C} Expression (3)

The reason why the solution of Expression (3) is V_{C} is that the open-circuit voltage converges to V_{C} if the voltage-change convergence time τ has elapsed from the time of termination of charge and discharge.

Further, Expression (4) below is obtained by substituting in Expression (2) the voltage-change convergence time τ selected in step S2.

V′_{OCV}(τ)=−B₁A₁ exp(−B₁τ)− . . . −Bₙ₊₁Aₙ₊₁ exp(−Bₙ₊₁τ)=0 Expression (4)

As pointed out above, the voltage-change convergence time τ is the time elapsed from termination of the charge and discharge of the secondary battery until a state is brought about in which the change per unit time (dV_{OCV}/dt) can be regarded as equal to 0. In the present embodiment, accordingly, the open-circuit voltage at stability of the secondary battery is calculated from the voltage characteristic expression on the assumption that the solution of the differential expression upon substitution of the voltage-change convergence time τ in the differential expression of the voltage characteristic expression yields 0.

Further, Expression (5) below is obtained from Expression (1) and a known open-circuit voltage V_{S} measured at the time of termination of charge and discharge (t=0).

V_{S}=V_{OCV}(0)=A₁+ . . . +Aₙ₊₁+V_{C} Expression (5)

Further, Expression (6-m) below for a number of measurements n is obtained from Expression (1) and the m-th (m is an integer ranging from 1 to n) measured open-circuit voltage V_{OCV}(tₘ) at a time tₘ after termination of charge and discharge.

V_{OCV}(tₘ)=A₁ exp(−B₁tₘ)+ . . . +Aₙ₊₁ exp(−Bₙ₊₁tₘ)+V_{C} Expression (6-m)

There is also calculated a proportion of change V′_{OCV}(tₘ) between two open-circuit voltages mutually adjacent in the measurement order, from among the n open-circuit voltages V_{OCV}(tₘ), and the open-circuit voltage Vₛ measured at the time of termination of charge and discharge (t=0), such that Expression (7-m) for a number of measurements n is obtained from V′_{OCV}(tₘ) and Expression (2).

V′_{OCV}(tₘ)=−B₁A₁ exp(−B₁tₘ)− . . . −Bₙ₊₁Aₙ₊₁·exp(−Bₙ₊₁tₘ) Expression (7-m)

The parameters A_{1 . . . n+1}, B_{1 . . . n+1}, V_{C} can be established by calculating the solution of the system of equations of Expression (3), Expression (4), Expression (5). Expression (6-m) and Expression (7-m). That is, the parameter V_{C} corresponding to the open-circuit voltage at stability of the secondary battery is calculated by calculating the solution of the system of equations.

In a hypothetical case where the number of measurements n is one, Expression (1) and Expression (2) are expressed as follows.

V_{OCV}(t)=A₁ exp(−B₁t)+A₂ exp(−B₂t)+V_{C} Expression (1)

V′_{OCV}(t)=−B₁A₁ exp(−B₁t)−B₂A₂exp(−B₂t) Expression (2)

Further, Expression (3) to Expression (5) are expressed as follows.

V_{OCV}(τ)=A₁ exp(−B₁τ)+A₂ exp(−B₂τ)+V_{C}=V_{C} Expression (3)

V′_{OCV}(τ)=−B₁A₁ exp(−B₁τ)−B₂A₂ exp(−B₂τ)=0 Expression (4)

V_{S}=V_{OCV}(0)=A₁+A₂+V_{C} Expression (5)

If the number of measurements n is one, there are obtained one Expression (6-1) and one Expression (7-1) below, respectively, as the above-described Expression (6-m) and Expression (7-m),

V_{OCV}(t₁)=A₁ exp(−B₁t₁)+A₂ exp(−B₂t₁)+V_{C} Expression (6-1)

V′_{OCV}(t₁)={V_{OCV}(t₁)−V_{S}}/t₁=−B₁A₁ exp(−B₁t₁)−B₂A₂·exp(−B₂t₁) Expression (7-1)

The solution of the system of equations of the five expressions (Expression (3) to Expression (7-1)) is calculated to calculate thereby the five parameters A₁, A₂, B₁, B₂, V_{C} and estimate the state of charge of the secondary battery from the calculated V_{C} (open-circuit voltage).

In the present embodiment, specifically, Expression (3) and Expression (4) are obtained by using the selected voltage-change convergence time τ in the voltage characteristic expression. By obtaining more expressions than in a case where the voltage-change convergence time τ is not used, it becomes possible to estimate the state of charge from fewer measured values of open-circuit voltage, and to shorten the time required for estimating the state of charge. The state of charge can obviously be estimated with yet higher precision, as compared with an instance where the voltage-change convergence time is not used, in a case where measured values of open-circuit voltage are used in a number identical to that when the voltage-change convergence time τ is not used.

After estimation of the state of charge of the secondary battery, it is determined whether the voltage-change convergence time τ has elapsed or not from the time of termination of charge and discharge (step S6); If it is determined that the voltage-change convergence time τ has not elapsed, the reliability of the estimated state of charge is calculated on the basis of a comparison between the time elapsed from the time of termination of charge and discharge up to the point in time when the open-circuit voltage 1 of the secondary battery is measured for the last time after termination of charge and discharge, and the voltage-change convergence time τ (step S7). Specifically, the reliability of the state of charge is calculated by computing t_{LAST}/τ where t_{LAST} is the time elapsed from the time of termination of charge and discharge up to the point in time when the open-circuit voltage 1 of the secondary battery is measured for the last time after termination of charge and discharge. This is based on the idea that the open-circuit voltage 1 has converged once the voltage-change convergence time τ has elapsed, and accordingly, the estimated state of charge is trustworthy.

After reliability calculation, the above-described process of calculating the open-circuit voltage at stability from the above-described voltage characteristic expression, estimating the state of charge, and calculating reliability, is repeated until the voltage-change convergence time τ has elapsed (steps S3 to 7). The state-of-charge estimation method of the present embodiment is terminated, by contrast, if in step S6 it is determined that the voltage-change convergence time τ has elapsed. This state-of-charge estimation method is performed every time that charge and discharge of the battery is terminated. In a case where charge and discharge is resumed before the voltage-change convergence time τ has elapsed, the state-of-charge estimation method is terminated even halfway during repetition of steps S3 to 7, and the state of charge that had been estimated thus far is taken as the state of charge that is estimated in accordance with the state-of-charge estimation method of the present embodiment.

Next, FIG. 5 is a block diagram illustrating a state-of-charge estimation device for carrying out the state-of-charge estimation method of the present embodiment. In the figure, a state-of-charge estimation device 2 is connected to a secondary battery 3. For instance, the state-of-charge estimation device 2 is made up of a computer that is installed in a vehicle, and the secondary battery 3 is made up of, for instance, a lithium ion battery installed in a vehicle.

The state-of-charge estimation device 2 is provided with a storage unit 20 and a computing unit 21. The storage unit 20 is made up of, for instance, a RAM or ROM, and stores the above-described voltage-change convergence times τ_{1-1 . . . X-Y} for each combination of state of charge of the secondary battery 3 at the time of termination of charge and discharge, as estimated on the basis of the integrated current value or the like, and temperature of the secondary battery 3 at the time of termination of charge and discharge. The computing unit 21 is made up for instance of a CPU or the like, and executes the above-described state-of-charge estimation method in accordance with a predefined program. Specifically, the operation of the computing unit 21 is as explained in FIG. 4 above.

Such a state-of-charge estimation method and state-of-charge estimation device involve measuring beforehand a voltage-change convergence time τ from termination of charge and discharge of the secondary battery until convergence of change in the open-circuit voltage 1, for each combination of state of charge of the secondary battery at the time of termination of charge and discharge, as estimated on the basis of an integrated current value or the like, and the temperature of the secondary battery at the time of termination of charge and discharge, and, upon termination of the charge and discharge of the secondary battery, selecting the voltage-change convergence time τ corresponding to the temperature and state of charge based on an integrated current value or the like at the time of termination of charge and discharge, and using the selected voltage-change convergence time τ in a voltage characteristic expression. Therefore, it becomes possible to estimate the state of charge using a smaller number of measured values of open-circuit voltage, and to shorten the time required for estimation of the state of charge. The state of charge can be estimated with yet higher precision, as compared with an instance where the voltage-change convergence time τ is not used, in a case where measured values of open-circuit voltage are used in a number identical to that when the voltage-change convergence time τ is not used.

The open-circuit voltage at stability of the secondary battery is calculated from the voltage characteristic expression by exploiting the feature whereby, upon substitution of the voltage-change convergence time τ in the differential expression of the voltage characteristic expression, the solution of the differential expression is 0. Therefore, this allows more expressions pertaining to a voltage characteristic expression to be obtained, and allows the state of charge to be estimated using a smaller number of measured values of open-circuit voltage.

Further, the open-circuit voltage at stability of the secondary battery is calculated from the voltage characteristic expression by using the measured open-circuit voltage of the secondary battery, and further using a proportion of change of open-circuit voltage between measured open-circuit voltages of the secondary battery. Therefore, the open-circuit voltage at stability can be calculated yet more reliably.

The parameter V_{C} corresponding to the open-circuit voltage at stability of the secondary battery is calculated as a result of the process explained in the embodiment, and hence the open-circuit voltage at stability can be calculated even more reliably.

Further, the reliability of the estimated state of charge is calculated on the basis of a comparison between the voltage-change convergence time τ and the time elapsed from the time of termination of charge and discharge up to the point in time when the open-circuit voltage of the secondary battery is measured for the last time after termination of charge and discharge. Therefore, it becomes possible to obtain a yardstick on the degree of reliability of the estimated state of charge.

1. A state-of-charge estimation method for estimating a state of charge of a secondary battery by approximating a time change in an open-circuit voltage of the secondary battery after termination of charge and discharge by a voltage characteristic expression, and calculating the open-circuit voltage from the voltage characteristic expression where the secondary battery is stable,
the method comprising the steps of:
measuring beforehand a voltage-change convergence time τ from termination of charge and discharge of the secondary battery until convergence of change in the open-circuit voltage, for each combination of state of charge of the secondary battery at the time of termination of charge and discharge and the temperature of the secondary battery at the time of termination of charge and discharge; and
upon termination of charge and discharge of the secondary battery, selecting the voltage-change convergence time τ corresponding to the state of charge and the temperature at the time of termination of charge and discharge, and using the selected voltage-change convergence time τ in the voltage characteristic expression.

2. The state-of-charge estimation method according to claim 1, wherein the voltage-change convergence time τ is substituted in a differential expression of the voltage characteristic expression, to calculate the open-circuit voltage at stability of the secondary battery.

3. The state-of-charge estimation method according to claim 2, wherein
the open-circuit voltage of the secondary battery is measured at the time of termination of charge and discharge, and the open-circuit voltage of the secondary battery after termination of charge and discharge is measured at least once; and
the open-circuit voltage at stability of the secondary battery is calculated from the voltage characteristic expression by further using the measured open-circuit voltages of the secondary battery and a proportion of change in open-circuit voltage between measured open-circuit voltages of the secondary battery.

4. The state-of-charge estimation method according to claim 3, wherein
the voltage characteristic expression is expressed by Expression (1) below, which includes parameters A_{1 . . . n+1}, B_{1 . . . n+1}, V_{C}, where t denotes the time elapsed from the time of termination of charge and discharge, and n denotes the number of measurements of the open-circuit voltage after termination of charge and discharge:
V_{OCV}(t)=A₁ exp(−B₁t)+ . . . +Aₙ₊₁ exp(−Bₙ₊₁t)+V_{C} Expression (1)
the differential expression is expressed by Expression (2) below:
V′_{OCV}(t)=−B₁A₁ exp(−B₁t)− . . . −Bₙ₊₁Aₙ₊₁ exp(−Bₙ₊₁t) Expression (2)
Expression (3) and Expression (4) below are obtained by substituting τ in the Expression (1) and the Expression (2):
V_{OCV}(τ)=A₁ exp(−B₁τ)+ . . . +Aₙ₊₁ exp(−Bₙ₊₁τ)+V_{C}=V_{C} Expression (3)
V′_{OCV}(τ)=−B₁A₁ exp(−B₁τ)− . . . −Bₙ₊₁Aₙ₊₁ exp(−Bₙ₊₁τ)=0 Expression (4)
Expression (5) below is obtained from the Expression (1) and a known open-circuit voltage V_{S} measured at the time of termination of charge and discharge (t=0):
V_{S}=V_{OCV}(0)=A₁+ . . . +Aₙ₊₁+V_{C} Expression (5)
Expression (6-m) below for the number of measurements n is obtained from Expression (1) and an m-th (m is an integer ranging from 1 to n) measured open-circuit voltage V_{OCV}(tₘ) at a time tₘ after termination of charge and discharge:
V_{OCV}(tₘ)=A₁ exp(−B₁tₘ)+ . . . +Aₙ₊₁ exp(−Bₙ₊₁tₘ)+V_{C} Expression (6-m)
Expression (7-m) below for the number of measurements n is obtained from the open-circuit voltage Vₛ, a proportion of change V′_{OCV}(tₘ) between two open-circuit voltages mutually adjacent in a measurement order, from among the n open-circuit voltages V_{OCV}(tₘ), and the Expression (2):
V′_{OCV}(tₘ)=−B₁A₁ exp(−B₁tₘ)− . . . −Bₙ₊₁Aₙ₊₁·exp(−Bₙ₊₁tₘ) Expression (7-m), and
the parameter V_{C} corresponding to the open-circuit voltage at stability of the secondary battery is calculated by solving the system of equations of Expression (3), Expression (4), Expression (5), Expression (6-m) and Expression (7-m).

5. The state-of-charge estimation method according to claim 3, wherein
measurement of the open-circuit voltage of the secondary battery after termination of charge and discharge is performed at predefined measurement intervals; and
reliability of the estimated state of charge is calculated on the basis of a comparison between the time elapsed from the time of termination of charge and discharge up to the point in time when the open-circuit voltage of the secondary battery is measured for a last time after termination of charge and discharge, and the voltage-change convergence time τ.

6. A state-of-charge estimation device that calculates an open-circuit voltage from a voltage characteristic expression where a secondary battery is at stable in which a time change of open-circuit voltage of the secondary battery is approximated after termination of charge and discharge, in order to estimate the state of charge of the secondary battery,
the device comprising:
a storage unit that stores a voltage-change convergence time τ from termination of charge and discharge of the secondary battery until convergence of change in the open-circuit voltage, for each combination of a state of charge of the secondary battery at the time of termination of charge and discharge and the temperature of the secondary battery at the time of termination of charge and discharge; and
a computing unit that, upon termination of charge and discharge of the secondary battery, selects the voltage-change convergence time τ corresponding to the state of charge and the temperature at the time of termination of charge and discharge, and uses the selected voltage-change convergence time τ in the voltage characteristic expression.

7. The state-of-charge estimation device according to claim 6, wherein the computing unit substitutes the voltage-change convergence time τ in a differential expression of the voltage characteristic expression, to calculate the open-circuit voltage at stability of the secondary battery.

8. The state-of-charge estimation device according to claim 7, wherein
the computing unit:
measures the open-circuit voltage of the secondary battery at the time of termination of charge and discharge, and measures the open-circuit voltage of the secondary battery after termination of charge and discharge at least once; and
calculates the open-circuit voltage at stability of the secondary battery from the voltage characteristic expression by further using the measured open-circuit voltages of the secondary battery and a proportion of change in open-circuit voltage between measured open-circuit voltages of the secondary battery.

9. The state-of-charge estimation device according to claim 8, wherein
the voltage characteristic expression is expressed by Expression (1) below, which includes parameters A_{1 . . . n+1}, B_{1 . . . n+1}, V_{C}, where t denotes the time elapsed from the time of termination of charge and discharge, and n denotes the number of measurements of the open-circuit voltage after termination of charge and discharge:
V_{OCV}(t)=A₁ exp(−B₁t)+ . . . +Aₙ₊₁ exp(−Bₙ₊₁t)+V_{C} Expression (1)
the differential expression is expressed by Expression (2) below:
V′_{OCV}(t)=−B₁A₁ exp(−B₁t)− . . . −Bₙ₊₁Aₙ₊₁ exp(−Bₙ₊₁t) Expression (2), and wherein the computing unit
obtains Expression (3) and Expression (4) below by substituting τ in the Expression (1) and the Expression (2):
V_{OCV}(τ)=A₁ exp(−B₁τ)+ . . . +Aₙ₊₁ exp(−Bₙ₊₁τ)+V_{C}=V_{C} Expression (3)
V′_{OCV}(τ)=−B₁A₁ exp(−B₁τ)− . . . −Bₙ₊₁Aₙ₊₁ exp(−Bₙ₊₁τ)=0 Expression (4)
obtains Expression (5) below from the Expression (1) and a known open-circuit voltage V_{S} measured at the time of termination of charge and discharge (t=0):
V_{S}=V_{OCV}(0)=A₁+ . . . +Aₙ₊₁+V_{C} Expression (5)
obtains Expression (6-m) below for the number of measurements n from Expression (1) and an m-th (m is an integer ranging from 1 to n) measured open-circuit voltage V_{OCV}(tₘ) at a time tₘ after termination of charge and discharge:
V_{OCV}(tₘ)=A₁ exp(−B₁tₘ)+ . . . +Aₙ₊₁ exp(−Bₙ₊₁tₘ)+V_{C} Expression (6-m)
obtains Expression (7-m) below for the number of measurements n from the open-circuit voltage Vₛ, a proportion of change V′_{OCV}(tₘ) between two open-circuit voltages mutually adjacent in a measurement order, from among the n open-circuit voltages V_{OCV}(tₘ), and the Expression (2):
V′_{OCV}(tₘ)=−B₁A₁ exp(−B₁tₘ)− . . . −Bₙ₊₁Aₙ₊₁·exp(−Bₙ₊₁tₘ) Expression (7-m), and
calculates the parameter V_{C} corresponding to the open-circuit voltage at stability of the secondary battery by solving a system of equations of Expression (3), Expression (4), Expression (5), Expression (6-m) and Expression (7-m).

10. The state-of-charge estimation device according to claim 8, wherein
measurement of the open-circuit voltage of the secondary battery after termination of charge and discharge is performed at predefined measurement intervals; and
the computing unit calculates reliability of the estimated state of charge on the basis of a comparison between the voltage-change convergence time τ and the time elapsed from the time of termination of charge and discharge up to the point in time when the open-circuit voltage of the secondary battery is measured for a last time after termination of charge and discharge.
